(19) United States
(12) Patent Application Publication
(10) Pub. No.: US 2013/0222282 A1
(43) Pub. Date: Aug. 29, 2013

(54) Structure of Wet-coating Transparent Conductive Film and the Application Thereof

(71) Applicants: Chiao-Ning Huang, Hsinchu City (TW); Yu-Ling Chen, Hsinchu City (TW); Tsui-Chi Chen, Hsinchu County (TW); Jong-Hsiang Lu, New Taipei City (TW); Chien-Cheng Chang, Taoyuan County (TW); Yu-Chun Chien, Taoyuan County (TW)

(72) Inventors: Chiao-Ning Huang, Hsinchu City (TW); Yu-Ling Chen, Hsinchu City (TW); Tsui-Chi Chen, Hsinchu County (TW); Jong-Hsiang Lu, New Taipei City (TW); Chien-Cheng Chang, Taoyuan County (TW); Yu-Chun Chien, Taoyuan County (TW)

(73) Assignee: FAR EASTERN NEW CENTURY CORPORATION, Taipei (TW)

(21) Appl. No.: 13/611,575

(22) Filed: Sep. 12, 2012

Related U.S. Application Data
(60) Provisional application No. 61/604,767, filed on Feb. 29, 2012.

(51) Int. Cl. B32B 7/02; G06F 3/041; H03K 17/975; B82Y 30/00

(52) U.S. Cl. 345/173; 428/212; 200/600; 977/742

(57) ABSTRACT

This invention discloses a structure of wet-coating transparent conductive film and the application thereof. The wet-coating transparent conductive film comprises a substrate layer, and a transparent conductive layer. The wet-coating transparent conductive film can further comprise an index matching layer between the substrate layer and the transparent conductive layer. The index matching layer and the transparent conductive layer can be formed by wet-coating process. Preferably, the mentioned wet-coating transparent conductive film can be widely applied in touch control module or touch control displaying device.

### BACKGROUND OF THE INVENTION

1. Field of the Invention

The present invention is generally related to a structure of conductive film, and more particularly to a structure of wet-coating transparent conductive film and the application thereof.

2. Description of the Prior Art

In recent years, many conveniently smart devices are developed, such as smart mobile phone, touch screen, touch panel calculator, electronic book, etc. With the development of these smart devices using lots of touch control technology, touch panel, including single-touch panel and multi-touch panel, becomes more and more important for the industry. In the prior art, the material of the transparent conductive film of touch panel is mostly selected from ITO sputter process.

FIG. 1 shows a conductive film structure in the prior art. On a substrate layer 120, there are a first index matching layer 140, a second index matching layer 160, and an Indium-Tin oxide (ITO) layer 180. The ITO layer 180 is formed onto the second index matching layer 160 by sputtering. In order to decrease the chromaticity difference between the light passing through the ITO layer 180 and the light from a lighting material at another side of the substrate layer 120, it is necessary to position at least two index matching layers between the substrate layer 120 and the ITO layer 180, wherein the reflective index of one of the index matching layers is larger than the reflective index of the substrate layer 120, and the reflective index of the other index matching layer is smaller than the reflective index of the substrate layer 120. Excluding reflective index, the material selection of the first index matching layer 140 and the second index matching layer 160 have to consider the following sputtering process of the ITO layer 180.

It is well-known for one skilled in the art that it is not easy to adjust the chromaticity difference by selecting the material from different reflective index. It is more difficult to adjust the chromaticity difference of transmitting light by employing two materials with different reflective index. Therefore, the above-mentioned transparent conductive film is not only using expensive material and manufacturing apparatus, but also using complex process to fabricate thereof.

For expanding the use of the conductive material on capacitance, the conductive material must provide higher transmittance property, and the etching mark is not visible. In the prior art, the transparent conductive film can show no etching mark by employing vacuum sputtering process. The cost of the material in the sputtering process, the vacuum requirement, and the technical threshold are all the reason causing the final product being so expensive. Moreover, the metal oxide like ITO will only present good transmittance and electric conductivity in a special optical thickness range. With the requirement of lower and lower resistance of conductive film, the thickness of the ITO layer in the mentioned conductive film is going to be increased. The increase of the thickness of the metal oxide is not only forcing manufacturer employing more expensive apparatus in the process, but also raising the material cost. Furthermore, in the sputtering process, the yield of the sputtering process will be decreased for increasing the thickness of metal oxide. In other words, when the resistance of conductive film becomes lower and lower, the manufacturing cost of the conductive film becomes higher and higher. So that the mentioned conductive film will lose price competitive ability and the final product attraction. Besides, with the increasing thickness of the metal oxide, the transparency of the conductive film is going to be sacrificed.

In view of the above matter, developing a novel transparent conductive film having the adventures of high transmittance, high electric conductivity, high yield, low resistance, flexible, simple manufacturing, not expensive apparatus and material is still an important task for the industry.

### SUMMARY OF THE INVENTION

In light of the above background, in order to fulfill the requirements of the industry, the present invention provides a novel transparent conductive film having the adventures of simple manufacturing, not expensive cost, high transmittance, high electric conductivity, high yield, low resistance, and flexible, so that the competitive ability of the industry can be improved.

One object of the present invention is to provide a structure of wet-coating transparent conductive film to simplify the manufacturing process, to raise the yield, and to reduce the manufacturing cost by employing wet-coating process.

Another object of the present invention is to provide a structure of wet-coating transparent conductive film to improve the transmittance ability, electric conductivity, yield, and flexibility of the transparent conductive film by selecting conductive material.

Still another object of the present invention is to provide a structure of wet-coating transparent conductive film to reduce resistance of the transparent conductive film by selecting conductive material.

Accordingly, the present invention discloses a structure of wet-coating transparent conductive film. The mentioned structure of wet-coating transparent conductive film comprises a substrate layer, and a transparent conductive layer. The mentioned structure of wet-coating transparent conductive film can further comprise an index matching layer placed between the substrate layer and the transparent conductive layer. The index matching layer and the transparent conductive layer is formed onto the substrate layer through wet-coating process. According to this invention, the structure of wet-coating transparent conductive film can simplify the manufacturing process, raise the yield, and reduce the manufacturing cost by employing wet-coating process. The structure of wet-coating transparent conductive film of this invention can provide excellent transmittance, and can efficiently decrease the chromaticity difference before etching and after etching process. Preferably, the structure of wet-coating transparent conductive film of this invention can be flexible, hitting-resistant, and sliding-resistant. That is, this invention discloses a structure of wet-coating transparent conductive film with greater competitive ability for industry.

### BRIEF DESCRIPTION OF THE DRAWINGS

The present disclosure can be described by the embodiments given below. It is understood, however, that the embodiments below are not necessarily limitations to the present disclosure, but are used to a typical implementation of the invention.

FIG. 1 shows a structure of wet-coating transparent conductive film in the prior art;

FIG. 2 shows a structure of wet-coating transparent conductive film according to this invention;

FIG. 3 shows manufacturing process of the structure of wet-coating transparent conductive film of this invention;

FIGS. 4A to 4I shows a touch control module with the structure of wet-coating transparent conductive film of this invention;

FIG. 4J and FIG. 4K respectively present a picture of a touch control module without index matching layer and a picture of a touch control module with a wet-coating transparent conductive film of this invention; and

FIG. 5 shows a touch control device with a wet-coating transparent conductive film of this invention.

### DESCRIPTION OF THE PREFERRED EMBODIMENTS

What probed into the invention is a structure of wet-coating transparent conductive film and the application thereof. Detailed descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention. Some preferred embodiments of the present invention will now be described in greater details in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

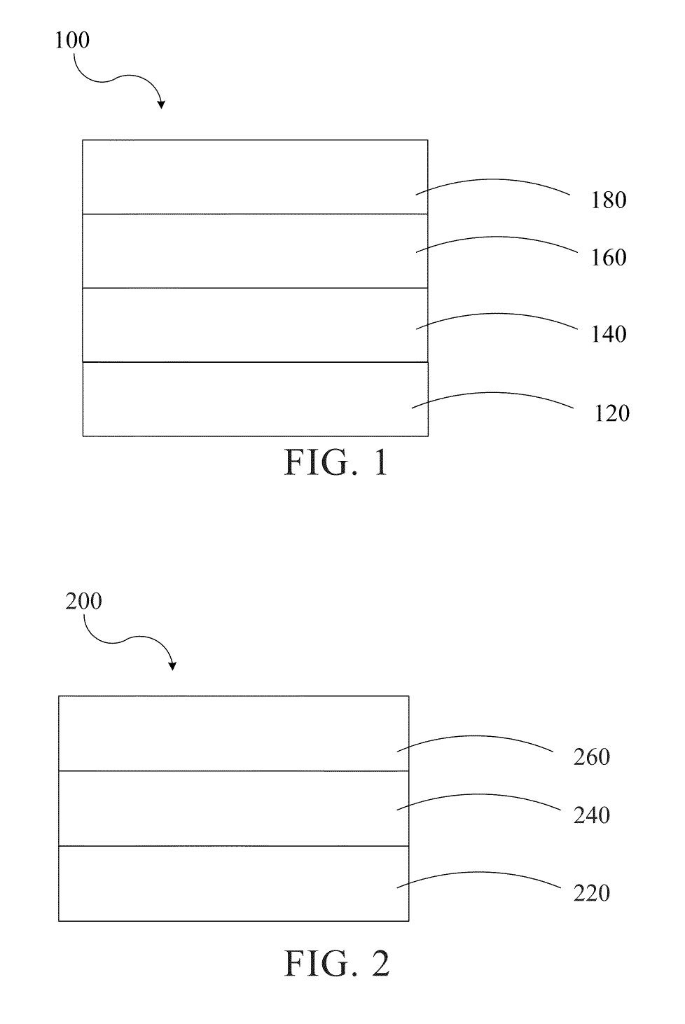

One preferred embodiment according to this specification discloses a structure of wet-coating transparent conductive film. FIG. 2 shows a structure of wet-coating transparent conductive film of this embodiment. Referred to FIG. 2, the structure of wet-coating transparent conductive film 200 comprises a substrate layer 220, an index matching layer 240, and a transparent conductive layer 260. The substrate layer 220 can be a polymer substrate with plasticity. In one preferred example of this embodiment, the substrate layer 220 is selected from one or the combination of the group consisting of the following: polycarbonate (PC), polyethylene terephthalate (PET), Poly(methacrylic acid methyl ester) (PMMA), triacetyl cellulose (TAC), Cyclo Olefin Polymer (COP), Polyimide (PI), Poly(ethylene naphthalate) (PEN). In one preferred example of this embodiment, the thickness of the substrate layer 220 is about 50-250 μm.

Referred to FIG. 2, the index matching layer 240 is formed on the substrate layer 220. According to this embodiment, the index matching layer 240 can be formed on the substrate layer 220 through wet-coating process. According to this embodiment, through destructive interference theory, the index matching layer 240 can efficiently improve the total transmittance of the structure of wet-coating transparent conductive film 200, and efficiently reduce the chromaticity difference between without etching process and etching process (0.3<Δb*<2). According to this embodiment, the index matching layer 240 comprises acrylic monomer, and metal oxide. In one preferred example, the mentioned metal oxide is nano filler, and is selected from one or the combination of group consisting of the following: Zirconium oxide, Titanium oxide, Zinc oxide, Aluminum oxide, Niobium oxide, Tantalum Oxide, Vanadium oxide. Preferably, in one preferred example of this embodiment, the index matching layer 240 can not only hidden the etching mark, but also improve the total transmittance of the structure of wet-coating transparent conductive film 200. In one preferred example, the reflective index of the index matching layer 240 is about 1.35-2.2. Preferably, the reflective index of the index matching layer 240 is about 1.5-1.8. In one preferred example, the thickness of the index matching layer 240 is about 10-500 nm.

Referred to FIG. 2, the transparent conductive layer 260 is formed on the index matching layer 240. According to this embodiment, the transparent conductive layer 260 can be formed onto the index matching layer 240 through wet-coating process. The transparent conductive layer 260 is selected from one or the combination from the group consisting of the following: carbon nano tube (CNT), and conductive polymer. In one preferred example, the mentioned conductive polymer is poly (3,4-ethylenedioxythiophene)/poly(styrenesulfonate) (PEDOT/PSS). In one preferred example of this embodiment, the resistance of the transparent conductive layer 260 is about 100-4000 Ω/□. In one preferred example of this embodiment, the thickness of the transparent conductive layer 360 is about 20-300 nm. According to this embodiment, the reflective index of the transparent layer 260 is less than the reflective index of the index matching layer 240.

In one preferred example of this embodiment, the structure of wet-coating transparent conductive film can further comprise a hard coat layer, not shown in the figure. The hard coat layer is placed between the substrate layer 220 and the index matching layer 240. The hard coat layer can make the substrate layer 220 full of mechanical strength and good steel wool at the same time.

In another preferred example of this embodiment, the structure of wet-coating transparent conductive film 200 can further comprise two hard coat layers, not shown in FIG. 2. The hard coat layers are respectively placed at the opposite side of the substrate layer 220, and one of the hard coat layers is placed between the substrate layer 220 and the index matching layer 240.

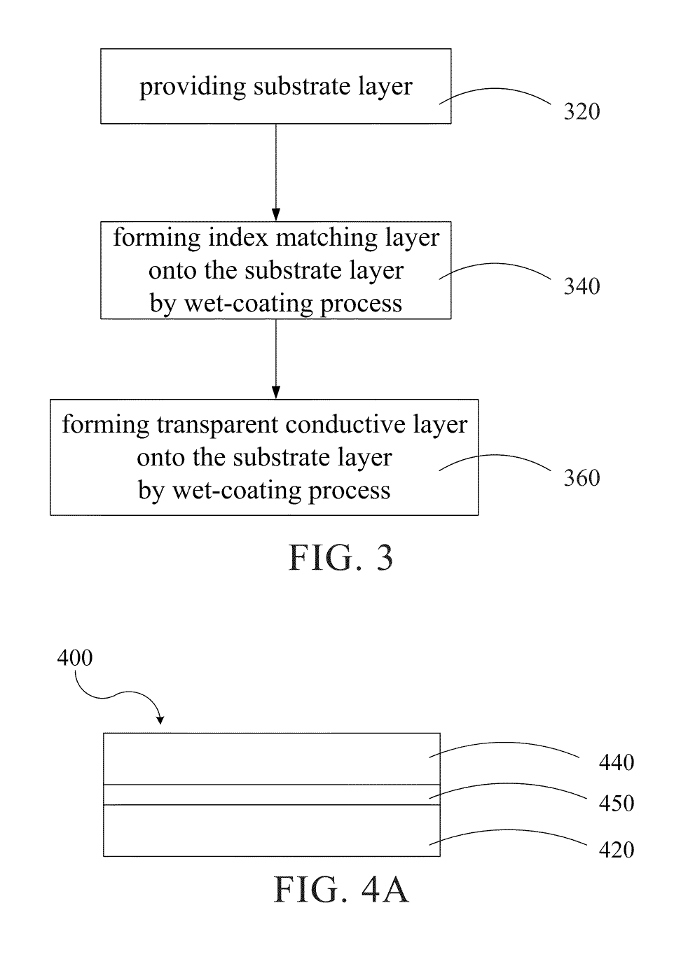

Another preferred embodiment of this invention discloses a manufacturing process of a wet-coating transparent conductive film. FIG. 3 shows a flowchart of a manufacturing process of a wet-coating transparent conductive film of this embodiment. Referred to FIG. 3, firstly, as shown in step 320, a substrate layer is provided. Then, an index matching layer is formed on the substrate layer by wet-coating process as step 340. Subsequently, a transparent conductive layer is formed on the index matching layer by wet-coating process as step 360.

In one preferred example of this embodiment, the transparent conductive layer comprises conductive material, and the mentioned conductive material is selected from one or the combination from the group consisting of the following: carbon nano tube (CNT), and conductive polymer. In one preferred example, the mentioned conductive polymer is poly(3,4-ethylenedioxythiophene)/poly(styrenesulfonate) (PEDOT/PSS). According to this embodiment, the reflective index of the transparent conductive layer is less than the reflective index of the index matching layer.

According to this example, the index matching layer can efficiently reduce the chromaticity difference between with out etching and etching process (0.3<Δb*<2). The mentioned index matching layer comprises acrylic monomer, and metal oxide. In one preferred example, the metal oxide is nanometer degree, and is selected from one or the combination of group consisting of the following: Zirconium oxide, Titanium oxide, Zinc oxide, Aluminum oxide, Niobium oxide, Tantalum Oxide, Vanadium oxide. Preferably, according to this preferred example, the index matching layer can not only hidden the etching mark, but also efficiently improve the total transmittance of the wet-coating transparent conductive film of this embodiment.

In one preferred example of this embodiment, the reflective index of the mentioned index matching layer is about 1.35-2.2. Preferably, the reflective index of the mentioned index matching layer is about 1.5-1.8. The thickness of the index matching layer is about 10-500 nm.

In one preferred example of this embodiment, the manufacturing process of wet-coating transparent conductive film further comprises a step for forming a hard coat layer. The hard coat layer is placed between the substrate layer and the index matching layer.

In another preferred example of this embodiment, the manufacturing process of wet-coating transparent conductive film further comprises a step for forming two hard coat layers. One of the hard coat layers is formed between the substrate layer and the index matching layer. The other hard coat layer is formed on the opposite side of the substrate layer opposite to the index matching layer. The hard coat layer(s) can make the substrate layer full of the mechanical strength and good steel wool at the same time.

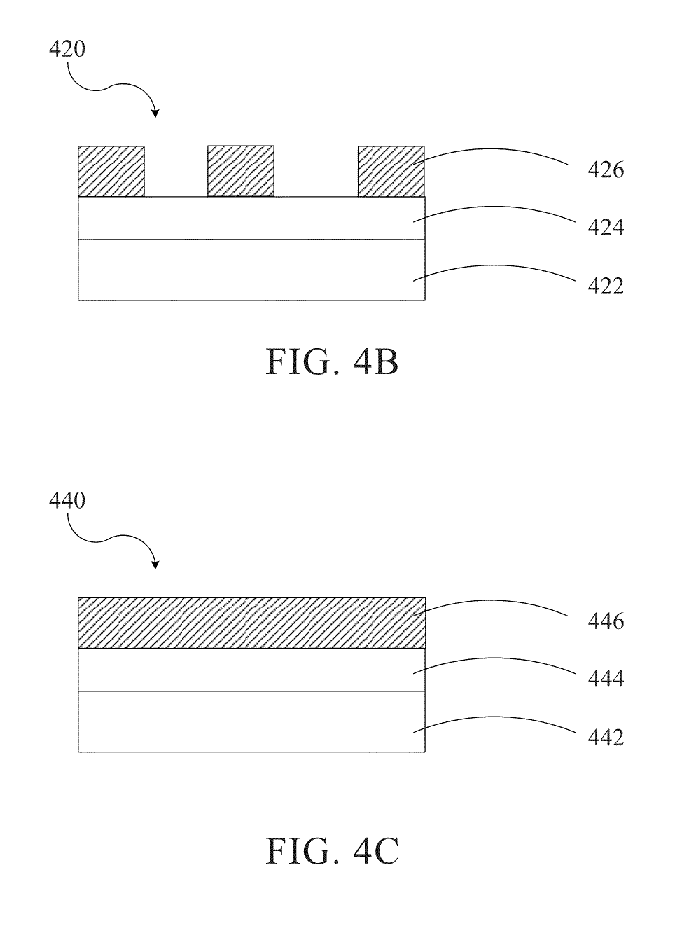

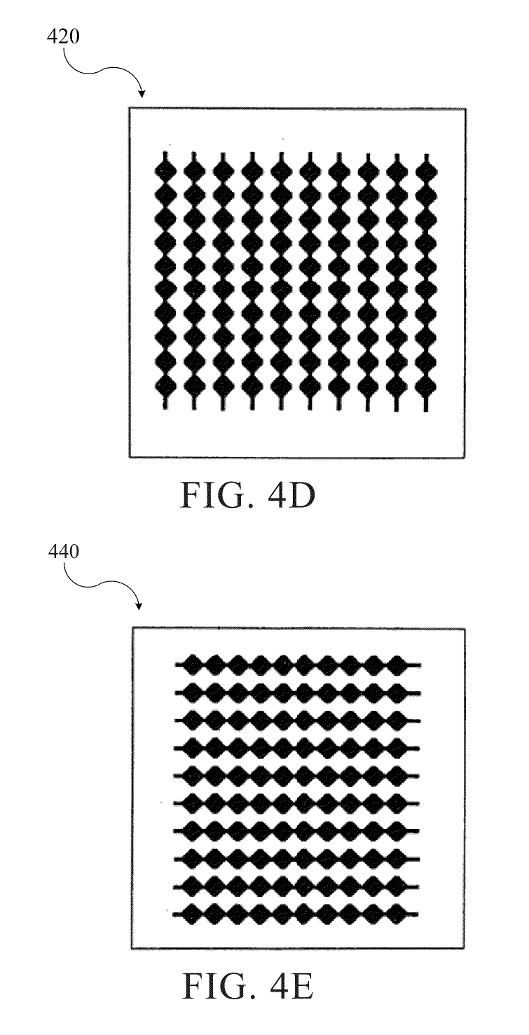

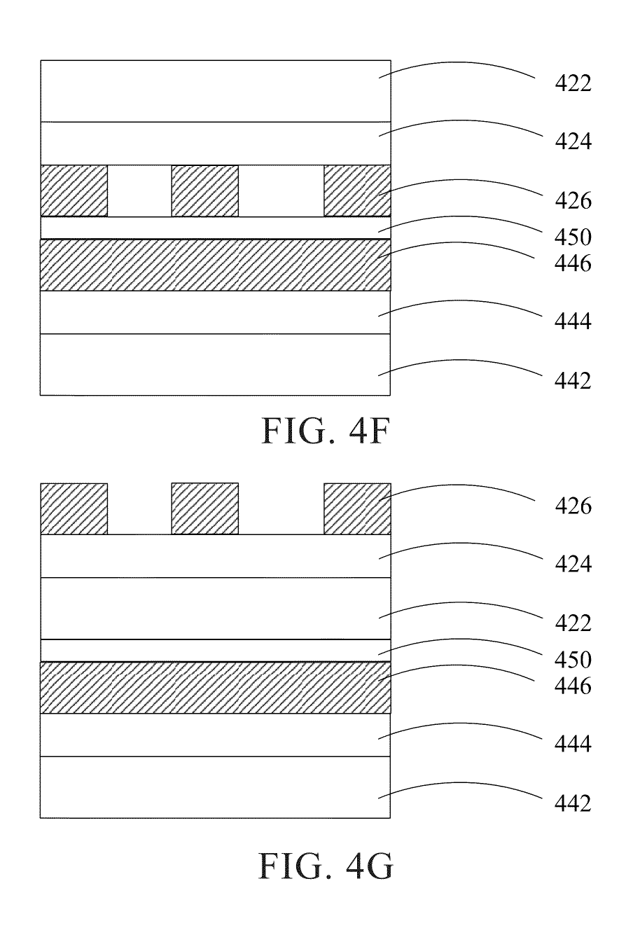

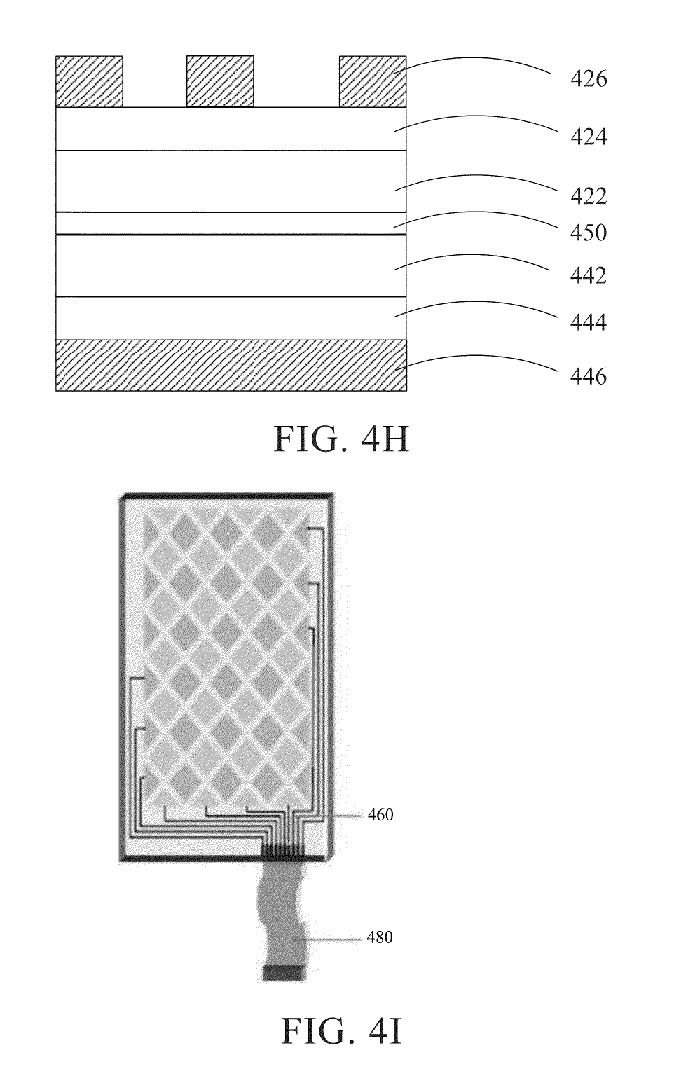

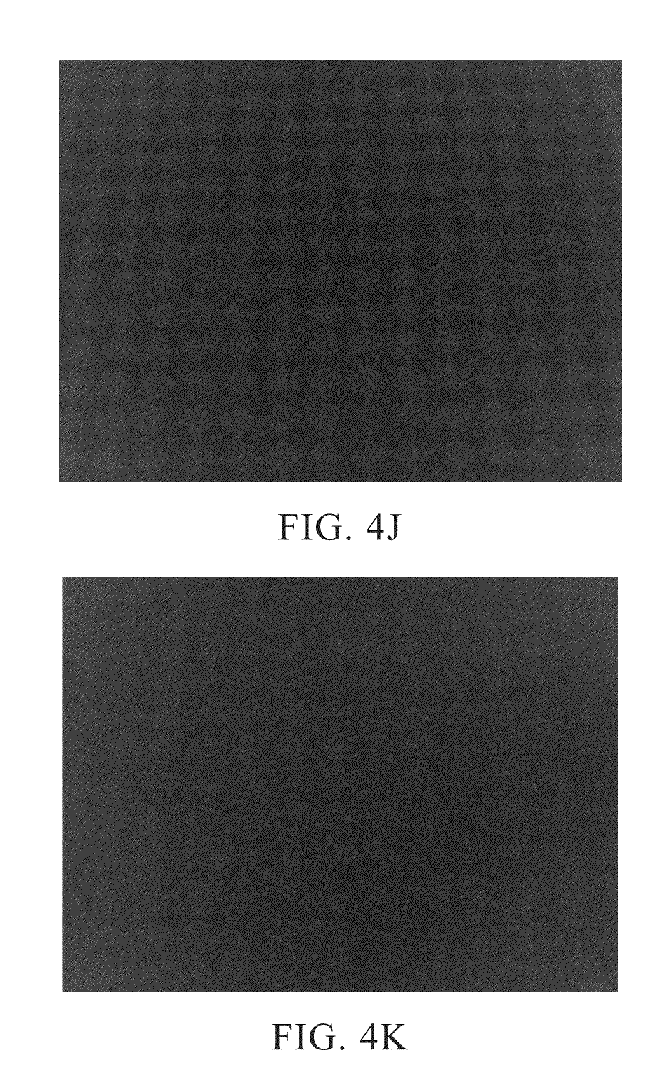

Still another preferred embodiment of this invention discloses a touch control module with wet-coating transparent conductive film. Referred to FIGS. 4A to 4K, the touch control module 400 comprises a first transparent conductive film 420, a second transparent conductive film 440, an adhesive layer 450, a conjugated electric circuit 460, and a soft electric panel 480. The first transparent conductive film 420 comprises a first substrate layer 422, a first index matching layer 424, and a first transparent conductive layer 426. The second transparent conductive film 440 comprises a second substrate layer 442, a second index matching layer 444, and a second transparent conductive layer 446. The adhesive layer 450 is employed for binding the first transparent conductive film 420 and the second transparent conductive film 440. In one preferred example of this embodiment, the adhesive layer is optical clear adhesive (OCA).

According to this embodiment, the first index matching layer 424 an the second index matching layer 444 can be respectively formed onto the first substrate layer 422 and the second substrate layer 442 by wet-coating process. The mentioned first index matching layer 424 an the second index matching layer 444 can efficiently improve the total transmittance of the first transparent conductive layer 420 and the second transparent conductive layer 440. The mentioned first index matching layer 424 and the second index matching layer 444 an also efficiently reduce the chromaticity difference between without etching and after etching (0.3<Δb*<2).

According to this embodiment, the composition of the mentioned first index matching layer 424 and the second index matching layer 444 respectively comprises acrylic monomer, and metal oxide. In one preferred example, the metal oxide is nano filler, and is selected from one or the combination of group consisting of the following: Zirconium oxide, Titanium oxide, Zinc oxide, Aluminum oxide, Niobium oxide, Tantalum Oxide, Vanadium oxide. Preferably, in one preferred example, the first index matching layer 424 and the second index matching layer 444 not only can hide the etching mark of the first transparent conductive layer 426 and the second transparent conductive layer 446, but also can efficiently improve the total transmittance of the touch control module 400 of this embodiment. In one preferred example, the reflective index of the mentioned first index matching layer 424 and the second index matching layer 444 is about 1.35-2.2. Preferably, the reflective index of the mentioned first index matching layer 424 and the second index matching layer 444 is about 1.5-1.8. In one preferred example of this embodiment, the thickness of the first index matching layer 424 and the second index matching layer 444 is respectively about 10-500 nm. According to this embodiment, the reflective index of the first transparent conductive layer 426 and the second transparent conductive layer 446 is respectively less than the reflective index of the first index matching layer 424 and the second index matching layer 444.

The composition of the mentioned first transparent conductive layer 426 and the second transparent conductive layer 446 is selected from one or the combination from the group consisting of the following: carbon nano tube (CNT), and conductive polymer. In one preferred example of this embodiment, the mentioned conductive polymer is poly(3,4-ethylenedioxythiophene)/poly(styrenesulfonate) (PEDOT/PSS). In one preferred example according to this embodiment, the resistance of the mentioned first transparent conductive layer 426 and the second transparent conductive layer 446 are respectively about 100-4000 Ω/□.

In one preferred example, the thickness of the first transparent conductive layer 426 and the second transparent conductive layer 446 is respectively about 20-300 nm.

Referred to FIG. 4D and FIG. 4E, the first transparent conductive layer 426 comprises a plurality of geometric layout and a plurality of first axial layout. Each of the first axial layouts is respectively electronic coupled with a plurality of the mentioned geometric layout. The second transparent conductive layer 446 comprises a plurality of geometric layout and a plurality of second axial layout. Each of the second axial layouts is respectively electronic coupled with a plurality of the mentioned geometric layout of the second transparent conductive layer 446. The above-mentioned geometric layouts and axial layouts can be formed by etching process, such as laser etching, micro-lithographic etching, screen-printing etching, plasma etching, and so on. The shape of the geometric layouts can be rhombus, circle, or other geometric shape. When binding the first transparent conductive film 420 and the second transparent conductive film 440, the first axial layout and the second layout are perpendicular to each other, and the geometric layout of the first transparent conductive layer 426 and the geometric layout of the second transparent conductive layer 446 are not overlapped each other while looking down at the touch control module 400. Moreover, as shown in FIGS. 4F to 4H, when binding the first transparent conductive film 420 and the second transparent conductive film 440, the first transparent conductive film 420 and the second transparent conductive film 440 can be bound in oriented direction, in same direction, or in opposite direction.

According to this embodiment, the conjugated electric circuit 460 comprises a plurality of conductive ink. Referred to FIG. 41, one end of the conjugated electric circuit 460 is respectively electronic coupled with the first axial layout and the second axial layout. The other end of the conjugated electric circuit 460 is electronic couple with the soft electric panel 480. When performing touch control, the touch signal detected by the first transparent conductive film 420 and the second transparent conductive film 440 will be transmitted to a signal processing device, not shown in the figures, through the conjugated electric circuit 460 and the soft electric panel 480.

FIG. 4J and FIG. 4K respectively show a touch control module without index matching layer, and a touch control panel with wet-coating transparent conductive film of this invention. The transparent conductive films in the touch control panels in FIG. 4J and FIG. 4K are formed by the method disclosed in the following Example 1. The difference is, when manufacturing the touch control module in FIG. 4J, the steps for forming the index matching layer are ignored. As shown in FIG. 4J, it is easily to find the rhombus shape of the etching pattern of the transparent conductive layer of the touch control module without index matching layer. Oppositely, as shown in FIG. 4K, there is no etching pattern of the transparent conductive layer shown in that figure. In comparison with FIG. 4J and FIG. 4K, it is apparent that the index matching layer according to this invention not only can successfully reduce the etching mark of the transparent conductive layer, but also can efficiently improve the total transmittance of the wet-coating transparent conductive film.

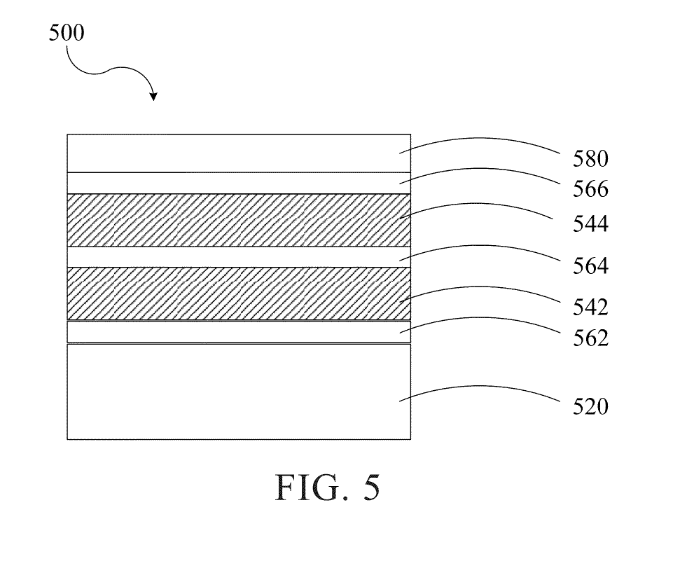

Still another embodiment of this invention discloses a touch control displaying device with wet-coating transparent conductive film. FIG. 5 shows a touch control displaying device of this embodiment. Referred to FIG. 5, a touch control displaying device 500 comprises a displaying module 520, a touch control module with wet-coating transparent conductive film 540, and protective layer 580. In one preferred example, the displaying module 520 is a liquid crystal module (LCM). The touch control module with wet-coating transparent conductive film 540 can be bound to the displaying module 520 with a first adhesive layer 562. In one preferred example, the touch control module with wet-coating transparent conductive film 540 can be the touch control module with wet-coating transparent conductive film disclosed in the above-mentioned embodiment. In one preferred example, the touch control module with wet-coating transparent conductive film 540 can be a capacitor touch control module. As shown in FIG. 5, the touch control module with wet-coating transparent conductive film 540 comprises a first transparent conductive film 542, a second transparent conductive film 544, and a second adhesive layer 564. The first transparent conductive film 542 comprises first substrate layer, first index matching layer, and first transparent conductive layer, not shown in the figure. The first index matching layer and the first transparent conductive layer can be sequentially formed on the first substrate layer through wet-coating process. The reflective index of the first index matching layer is greater than the reflective index of the first transparent conductive layer. The second transparent conductive film 544 comprises second substrate layer, second index matching layer, and second transparent conductive layer, not shown in the figure. The second index matching layer and the second transparent conductive layer can be formed on the second substrate layer through wet-coating process. The reflective index of the second index matching layer is greater than the reflective index of the second transparent conductive layer.

According to this embodiment, the touch control module with wet-coating transparent conductive film 540 can further comprise a conjugated electric circuit, and a soft electric panel, not shown in the figure. The touch control signal detected by the first transparent conductive film 542 and the second transparent conductive film 544 can be transmitted through the conjugated electric circuit and the soft electric panel to a signal processing device, not shown in the figure. The protective layer 580 can be bound to the touch control module with wet-coating transparent conductive film 540 by a third adhesive layer 566. The protective layer 566 can be employed to keep the touch control displaying device 500 from any scratch injury. In one preferred example of this embodiment, the protective layer 580 can further comprise anti-glare material. In another preferred example, the protective layer 580 can further comprise anti-reflection material.

The preferred examples of the structure and fabricating method for the structure of wet-coating transparent conductive film and the application thereof according to the invention are described in the following. However, the scope of the invention should be based on the claims, but is not restricted by the following examples.

### EXAMPLE 1

A 188 μm thickness PET film (A4300, registered trademark, produced by TOYOBO) is employed as a substrate. Both side of the substrate is coated with a solution with 32.5 wt % acrylic resin in methyl ethyl ketone (MEK) by wire-bar. After drying at 80° C. for 2 minutes and UV curing with 200 mj/cm² energy, two 5 μm hard coat layers are respectively formed on each side of the substrate. Subsequently, an index matching solution is coated onto one surface of the hard coat layer on the substrate by wire-bar. The index matching solution comprises 3 wt % titanium oxide, 3 wt % silicon oxide, and 93 wt % methyl iso-butyl ketone (MIBK). After drying at 90° C. for 2 minutes, an index matching layer with 100 nm thickness is formed on the hard-coat layer. Then, a CNT coating solution is coated onto the index matching layer by wire-bar. After drying at 100° C. for 2 minutes, an organic transparent conductive film with high transmission and low resistance is obtained. The total transmittance of the organic transparent conductive film is 88%, and the surface resistance of the organic transparent conductive film is 200 Ω/□.

### EXAMPLE 2

A 188 μm thickness PET film (A4300, registered trademark, produced by TOYOBO) is employed as a substrate. Both side of the substrate is coated with a hard coat solution with 32.5 wt % acrylic resin in methyl ethyl ketone (MEK) by wire-bar. After drying at 80° C. for 2 minutes and UV curing with 200 mj/cm² energy, two 5 μm hard coat layers are respectively formed on each side of the substrate. Subsequently, an index matching solution is coated onto one surface of the hard coat layer on the substrate by wire-bar. The index matching solution comprises 3 wt % zirconium oxide, 3 wt % light-sensitive resin, and 93 wt % methyl iso-butyl ketone (MIBK). After drying at 90° C. for 2 minutes and UV curing with 200 mj/cm² energy, an index matching layer with 100 nm thickness is formed thereon. Then, a CNT coating solution is coated onto the index matching layer by wire-bar. After drying at 100° C. for 2 minutes, an organic transparent conductive film with high transmission and low resistance is obtained. The total transmittance of the organic transparent conductive film is 88%, and the surface resistance of the organic transparent conductive film is 200

### COMPARATIVE EXAMPLE 1

A 188 μm thickness PET film (A4300, registered trademark, produced by TOYOBO) is employed as a substrate. Both side of the substrate is coated with a solution with 32.5 wt % acrylic resin in methyl ethyl ketone (MEK) by wire-bar. After drying at 80° C. for 2 minutes and UV curing with 200 mj/cm² energy, two 5 μm hard coat layers are respectively formed on each side of the substrate. Then, a CNT coating solution is coated onto the index matching layer by wire-bar. After drying at 100° C. for 2 minutes, an organic transparent conductive film with high transmission and low resistance is obtained. The total transmittance of the organic transparent conductive film is 86%, and the surface resistance of the organic transparent conductive film is 200

### COMPARATIVE EXAMPLE 2

A 188 μm thickness PET film (A4300, registered trademark, produced by TOYOBO) is employed as a substrate. Both side of the substrate is coated with a solution with 32.5 wt % acrylic resin in methyl ethyl ketone (MEK) by wire-bar. After drying at 80° C. for 2 minutes and UV curing with 200 mj/cm² energy, two 5 μm hard coat layers are respectively formed on each side of the substrate. Subsequently, an index matching solution is coated onto one surface of the hard coat layer on the substrate by wire-bar. The index matching solution comprises 2 wt % Fluoro-silane polymer, and 98 wt % methyl iso-butyl ketone (MIBK). After drying at 90° C. for 2 minutes, an index matching layer with 100 nm thickness is formed on the hard-coat layer. Then, a CNT coating solution is coated onto the index matching layer by wire-bar. After drying at 100° C. for 2 minutes, an organic transparent conductive film with high transmission and low resistance is obtained. The total transmittance of the organic transparent conductive film is 84%, and the surface resistance of the organic transparent conductive film is 200 Ω/□.

### COMPARATIVE EXAMPLE 3

Firstly, the manufacturing steps in the above-mentioned Example 2 are employed to form a based substrate comprising a PET film, and a hard coat layer and an index matching layer on the PET film. Subsequently, the mentioned based substrate is sent into a magnetic enhanced sputtering chamber, and the material of the sputtering target is ITO (In₂Ox:SnOₓ=90:10 by weight). When the mentioned chamber is vacuumed to 3×10⁻⁶ torr, Ar and O₂ are introduced into the mentioned chamber as the sputtering gas, wherein the sputtering gas is O₂/Ar=0.02. In the sputtering process, the work pressure is 5×10⁻⁴ torr, the work intensity is 4 KW, and the based substrate is at room temperature. After the sputtering process, a 30 nm thickness ITO conductive layer is formed on the based substrate to form an ITO conductive film. Through measuring, the surface resistance of the ITO conductive film is 217 Ω/□, the total transmittance of the ITO conductive film is 88.42%, and b* is 3.59. After etching the mentioned ITO conductive film with 5 wt % HCl for 3 minutes, the total transmittance of the etched area of the ITO conductive film is measured as 87.81%, and b* is −0.67.

TABLE 1

| | reflective index | Total | Chromaticity |
|---|---|---|---|
| | of index | transmittance | difference |
| | matching layer | (%) | Δb* |
| Example 1 | 1.75 | 88% | 1.08 |
| Example 2 | 1.60 | 88% | 2.67 |
| Comparative | — | 86% | 5.52 |
| Example 1 | | | |
| Comparative | 1.33 | 84% | 2.52 |
| Example 2 | | | |
| Comparative | 1.33 | 84% | 2.52 |
| Example 3 | | | |

As shown in the Table 1, there is no index matching layer employed in the Comparative Example 1, and the chromaticity difference between without etching and etching process in the Comparative Example 1 is very obvious (Δb*>5). In the Comparative Example 2, the reflective index of the index matching layer is 1.33 less than 1.46 (the reflective index of the transparent conductive layer). The index matching layer in the Comparative Example 2 can hide the etching mark, but cannot improve the transmittance of the transparent conductive film. According to the market requirement, the total transmittance of a transparent conductive film must be larger than 88%, so that the transparent conductive film can be employed in next product application. On the other hand, referred to Example 1 and Example 2, the transparent conductive film can provide excellent property on the chromaticity difference between without etching and etching process, and an excellent performance on the total transmittance. So that the wet-coating transparent conductive film of this invention can satisfy the market requirement. From the Comparative Example 3 and Example 2, when the constitution of the transparent conductive layer is changed from CNT conductive coating solution into ITO, the etching mark of the transparent conductive layer becomes clear, referred to Table 1. That is because of the reflective index of the ITO transparent conductive layer is not less than the reflective index of the index matching layer. In other words, the design disclosed in this application does not be proper to a transparent conductive film with ITO transparent conductive layer.

According to this invention, in order to achieve no etching mark, a transparent conductive film can comprise an index matching layer formed between the substrate layer and the transparent conductive layer through wet-coating process. The mentioned index matching layer not only can hide the etching mark, but also can efficiently improve the total transmittance of the wet-coating transparent conductive film of this invention. For the most part, the index matching layer can achieve the mentioned purposes according to destructive interference theory. When the reflective index of the index matching layer is greater than the reflective index of the substrate layer and transparent conductive layer, the chromaticity difference between without etching and etching process will become invisible. Preferably, when controlling the reflective index of the index matching layer in 1.5-1.8, the chromaticity difference between without etching and etching process will become invisible (0.3<Δb*<2). In order to adjust the reflective index of the index matching layer, the component material of the index matching layer can comprise acrylic monomer, and additional nano metal oxide as filler.

In the prior art, because of the condition of the sputtering process, it is limited on the selection of the component material of the index matching layer. Therefore, it is usually employing the combination of multiple index matching layers to adjust proper reflective index for reducing the etching mark. According to this invention, the index matching layer is formed on the substrate layer through wet-coating process. Because the condition of wet-coating process provides less limitation to the selection of the component material of the index matching layer, the wet-coating transparent conductive film of this invention can achieve the purpose of shielding mark by employing only one index matching layer.

According to this invention, the hard coat layer, index matching layer, and transparent conductive layer in the structure of wet-coating transparent conductive film can be formed by wet-coating process. Comparing with sputtering process in the prior art, the wet-coating process employs more un-expensive apparatus, and more friendly manufacturing process, and provides larger film-forming area, and more efficiently usage of material. Preferably, in one preferred example according to this invention, the manufacturing can be further simplified by employing roll-to-roll coating technology to form the hard coat layer, index matching layer, and the transparent conductive layer. Therefore, this application discloses a structure of transparent conductive film and the manufacturing process thereof with lower manufacturing cost, higher yield, and stronger competitive ability. Moreover, this invention also discloses application of the wet-coating transparent conductive film.

More preferably, the layout in the wet-coating transparent conductive film of this invention can be formed during wet-coating process. Comparatively, the layout in the prior art transparent conductive film is formed by etching process, and the condition of the etching process must be tested and modulated with the difference of the metal oxide and the index matching layer of the transparent conductive film after the sputtering process. That is, the transparent conductive film of this invention is more simple and efficient than the transparent conductive film in the prior art. Additionally, it is necessary for the transparent conductive film in the prior art to employ at least two index matching layer between the substrate layer and the transparent conductive layer. And, the material selection and the manufacturing of one of the index matching layers must be limited by the following sputtering process. On the other hand, in the transparent conductive film of this invention, only one index matching layer is necessary, and the material selection and the manufacturing of the index matching layer will not be limited by the following process for the transparent conductive layer.

Furthermore, flexible conductive material can be used in the transparent conductive layer of this invention, so that the transparent conductive film of this invention can provide excellent flexibility. More preferably, the transparent conductive layer of this invention can also provide great performance on hitting resistance and sliding resistance, so that the transparent conductive film of this invention is very durable. Therefore, the wet-coating transparent conductive film of this invention can provide more widely application and more competitive ability than the transparent conductive film in the prior art.

More preferably, according to this invention, the wet-coating transparent conductive film can be widely applied in touch control displaying device, especially applied in displaying device with projective capacitive touch panel. The mentioned touch control displaying device can be smart mobile phone, touch screen, touch panel calculator, touch control liquid crystal display (LCD), touch control organic light emitting diode (OLED) display, electronic book, touch control active-matrix organic light emitting diode (AMOLED) display, smart window, e-paper, and other single-touch displaying device or multi-touch panel displaying device.

In summary, we have reported a wet-coating transparent conductive film and the application thereof. The wet-coating transparent conductive film comprises a substrate layer, an index matching layer, and a transparent conductive layer. The index matching layer and the transparent conductive layer can be formed by wet-coating process. Through wet-coating process, the manufacturing process of the wet-coating transparent conductive film of this invention can be more simplified, lower cost, and higher yield than the manufacturing process of the transparent conductive film in the prior art. Preferably, the wet-coating transparent conductive film of this invention not only can provide higher total transmittance, but also can efficiently reduce the chromaticity difference between without etching and after etching process. More preferably, the wet-coating transparent conductive film also can provide excellent flexibility, hitting resistance, and sliding resistance. Thus, this invention can provide a wet-coating transparent conductive film with excellent performance and competitive ability for the industry. Furthermore, the wet-coating transparent conductive film of this invention can be applied in touch control module, and touch control displaying device. When the wet-coating transparent conductive film of this invention used in touch control module or touch control displaying device, the etching mark of the transparent conductive film will be efficiently reduced, and the total transmittance of the touch control module/touch control displaying device will be efficiently improved. More preferably, the above-mentioned wet-coating transparent conductive film not only can provide excellent performance, but also can simplify the manufacturing process, decrease manufacturing cost, and increase producing yield. Therefore, through employing the wet-coating transparent conductive film of this invention, the product competitive ability of the touch control module/touch control displaying device can be efficiently improved.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A wet-coating transparent conductive film comprising:
a substrate layer;
an index matching layer, wherein said index matching layer is formed on said substrate layer by wet-coating process; and
a transparent conductive layer on said index matching layer, the reflective index of said index matching layer is greater than the reflective index of said transparent conductive layer.

2. The wet-coating transparent conductive film according to claim 1, wherein said substrate layer comprises a polymer material with plasticity, wherein the polymer material is selected from one or the combination of the group consisting of the following: polycarbonate (PC), polyethylene terephthalate (PET), Poly(methacrylic acid methyl ester) (PMMA), triacetyl cellulose (TAC), Cyclo Olefin Polymer (COP), Polyimide (PI), Poly(ethylene naphthalate) (PEN).

3. The wet-coating transparent conductive film according to claim 1, wherein the reflective index of said index matching layer is 1.5-1.8, wherein the reflective index of said index matching layer is 1.3-1.6.

4. The wet-coating transparent conductive film according to claim 1, wherein said transparent conductive layer is selected from one or the combination of the group consisting of the following: carbon nano tube (CNT), and conductive polymer.

5. The wet-coating transparent conductive film according to claim 4, wherein the conductive polymer is poly(3,4-ethylenedioxythiophene)/poly(styrenesulfonate) (PEDOT/PSS).

6. The wet-coating transparent conductive film according to claim 1, wherein the resistance of said transparent conductive layer is 100-4000 Ω/□.

7. The wet-coating transparent conductive film according to claim 1, wherein said index matching layer comprises acrylic monomer, and metal oxide, wherein the metal oxide is selected from one or the combination of the group consisting of the following: Zirconium oxide, Titanium oxide, Zinc oxide, Indium Tin oxide, Aluminum oxide, Niobium oxide, Tantalum oxide, Vanadium oxide.

8. A touch control module with wet-coating transparent conductive film comprising:
a first wet-coating transparent conductive film, the first wet-coating transparent conductive film comprises a first substrate layer, a first index matching layer, and a first transparent conductive layer, wherein the reflective index of the first index matching layer is greater than the reflective index of the first transparent conductive layer;
a second wet-coating transparent conductive film, the second wet-coating transparent conductive film comprises a second substrate layer, a second index matching layer, and a second transparent conductive layer, wherein the reflective index of the second index matching layer is greater than the reflective index of the second transparent conductive layer;
a conjugated electric circuit; and
a soft electric panel, wherein one end of the conjugated electric circuit is respectively electronic coupled with the first transparent conductive layer and the second transparent conductive layer, wherein the other end of the conjugated electric circuit is electronic coupled with the soft electric panel.

9. The touch control module with wet-coating transparent conductive film according to claim 8, wherein the first transparent conductive layer comprises a plurality of geometric layout and a plurality of first axial layout, wherein the second transparent conductive layer comprises a plurality of geometric layout and a plurality of second axial layout, when binding the first transparent conductive film and the second transparent conductive film, the first axial layout and the second layout are perpendicular to each other, and the geometric layout of the first transparent conductive layer and the geometric layout of the second transparent conductive layer are not overlapped each other.

10. The touch control module with wet-coating transparent conductive film according to claim 8, wherein conjugated electric circuit comprises a plurality of conductive ink.

11. The touch control module with wet-coating transparent conductive film according to claim 8, wherein the reflective index of the first index matching layer and the second index matching layer is 1.5-1.8, wherein the reflective index of the first transparent conductive layer and the second transparent conductive layer is 1.3-1.6.

12. The touch control module with wet-coating transparent conductive film according to claim 8, wherein the composition of the first transparent conductive layer and the second transparent conductive layer is selected from one or the combination from the group consisting of the following: carbon nano tube (CNT), and conductive polymer.

13. The touch control module with wet-coating transparent conductive film according to claim 12, wherein the conductive polymer is poly(3,4-ethylenedioxythiophene)/poly(styrenesulfonate) (PEDOT/PSS).

14. The touch control module with wet-coating transparent conductive film according to claim 8, wherein the resistance of the first transparent conductive layer and the second transparent conductive layer is 100-4000 Ω/□.

15. The touch control module with wet-coating transparent conductive film according to claim 8, wherein the composition of the first index matching layer and the second index matching layer respectively comprises acrylic monomer, and metal oxide, wherein the metal oxide is selected from one or the combination of group consisting of the following: Zirconium oxide, Titanium oxide, Zinc oxide, Aluminum oxide, Niobium oxide, Tantalum Oxide, Vanadium oxide.

16. A touch control displaying device with wet-coating transparent conductive film comprising:
a displaying module;
a touch control module with wet-coating transparent conductive film, wherein the touch control module with wet-coating transparent conductive film is bound to the displaying module by a first adhesive layer, wherein the touch control module with wet-coating transparent conductive film comprises a first transparent conductive film, and a second transparent conductive film, wherein the second transparent conductive film is bound to the first transparent conductive film by a second adhesive layer; and
a protective layer, wherein the protective layer is bound to the touch control module with wet-coating transparent conductive film by a third adhesive layer;
wherein the first transparent conductive film comprises a first substrate layer, a first index matching layer, and a first transparent conductive layer, wherein the first index matching layer is between the first substrate layer and the first transparent conductive layer, wherein the reflective index of the first index matching layer is greater than the reflective index of the first transparent conductive layer, wherein the second transparent conductive film comprises a second substrate layer, a second index matching layer, and a second transparent conductive layer, wherein the second index matching layer is between the second substrate layer and the second transparent conductive layer, wherein the reflective index of the second index matching layer is greater than the reflective index of the second transparent conductive layer.

17. The touch control displaying device with wet-coating transparent conductive film according to claim 16, wherein the reflective index of the first index matching layer and the second index matching layer is respectively 1.5-1.8, wherein the reflective index of the first transparent conductive layer and the second transparent conductive layer is respectively 1.3-1.6.

18. The touch control displaying device with wet-coating transparent conductive film according to claim 16, wherein the composition of the first transparent conductive layer and the second transparent conductive layer is selected from one or the combination from the group consisting of the following: carbon nano tube (CNT), and conductive polymer.

19. The touch control displaying device with wet-coating transparent conductive film according to claim 18, wherein the conductive polymer is poly(3,4-ethylenedioxythiophene)/poly(styrenesulfonate) (PEDOT/PSS).

20. The touch control displaying device with wet-coating transparent conductive film according to claim 16, wherein the resistance of the first transparent conductive layer and the second transparent conductive layer is 100-4000 Ω/□.

21. The touch control displaying device with wet-coating transparent conductive film according to claim 16, wherein the composition of the first index matching layer and the second index matching layer respectively comprises acrylic monomer, and metal oxide, wherein the metal oxide is selected from one or the combination of group consisting of the following: Zirconium oxide, Titanium oxide, Zinc oxide, Aluminum oxide, Niobium oxide, Tantalum Oxide, Vanadium oxide.

22. The touch control displaying device with wet-coating transparent conductive film according to claim 16, wherein the touch control module with wet-coating transparent conductive film is a capacitor touch control module.
